(19) United States
(12) Patent Application Publication
(10) Pub. No.: US 2024/0347462 A1
(43) Pub. Date: Oct. 17, 2024

(54) METHOD FOR FORMING AN INSULATING LAYER PATTERN, PRECURSORS USED IN PATTERN FORMATION AND A SEMICONDUCTOR DEVICE

(71) Applicant: DONGJIN SEMICHEM CO., LTD., Incheon (KR)

(72) Inventors: Ha Kyung YUN, Hwaseong-si (KR); Jae Woo LEE, Hwaseong-si (KR); Jun Young KIM, Hwaseong-si (KR); So Jeong YEO, Hwaseong-si (KR); Han jin LEE, Hwaseong-si (KR); Pil Soo KIM, Hwaseong-si (KR); Jang Keun SIM, Hwaseong-si (KR); Cheol Kyu BOK, Hwaseong-si (KR)

(21) Appl. No.: 18/751,201

(22) Filed: Jun. 22, 2024

Related U.S. Application Data
(63) Continuation of application No. PCT/KR2022/019298, filed on Nov. 30, 2022.

(30) Foreign Application Priority Data
Dec. 30, 2021 (KR) 10-2021-0192643

(51) Int. Cl. H01L 23/532; C23C 16/02; C23C 16/40; C23C 16/455; H01L 21/02

(52) U.S. Cl. CPC H01L 23/5329; C23C 16/0236; C23C 16/401; C23C 16/45553; H01L 21/02164; H01L 21/0217; H01L 21/02315

(57) ABSTRACT

A method for forming an insulating layer pattern includes providing a substrate comprising two or more different types of dielectric layer regions; and selectively forming a blocking layer on the substrate to include a first region and a second region. On the first region, the blocking layer is formed, whereas on the second region, no blocking layer is formed or the blocking layer is formed less than in the first region. The difference in water contact angle between the first region and the second region is within the range of 7 to 50 degrees.

### CROSS-REFERENCE TO RELATED APPLICATIONS

This application is a Continuation of International Application No. PCT/KR2022/019298 filed Nov. 30, 2022, which claims priority from Korean Application No. 10-2021-0192643 filed Dec. 30, 2021. The aforementioned applications are incorporated herein by reference in their entireties.

### BACKGROUND

### 1. Technical Field

The present invention relates to a method for forming an insulating layer pattern, precursors used in pattern formation, and a semiconductor device.

### 2. Description of the Related Art

Semiconductor devices based on silicon materials have achieved a continuous reduction in fine line widths due to the rapid development of conventional top-down patterning technology and three-dimensional structuring and methods enabling mass manufacturing of nanostructures have been dominantly employed.

Traditional top-down optical lithography involves several complex process steps, including applying photoresist (PR), conducting heat treatment, aligning pattern masks, patterning PR through photolithography, and etching the underlying thin film according to the PR pattern. As a result, as pattern size decreases, more processing time and cost are required.

In particular, for the formation of ultrafine patterns of 10 nm or less, the introduction of new extreme ultraviolet (EUV) exposure equipment incurs significant costs. However, technical issues such as non-uniformity in pattern line width (critical dimension, CD) and alignment (overlay), pattern loading effects, surface roughness (line edge roughness; LER, line width roughness; LWR) problem, and low pellicle efficiency are limiting the ultra-fineness and precision of pattern formation.

Therefore, a new patterning paradigm technology is needed that can selectively form precise patterns in desired areas within a multidimensional structure of 10 nm or less and can reduce process time and cost by simplifying the process steps. Area-Selective Atomic Layer Deposition (AS-ALD, also known as ASD) is being researched as a next-generation alternative patterning process, effectively utilizing the surface reaction characteristics of ALD processes to selectively form precise atomic-level thin films in an upward (bottom-up) manner on selectively chosen areas above multi-colored patterns (i.e., patterns with various underlying materials).

Therefore, the AS-ALD process can form ultra-fine nanostructure patterns through modifying the surface properties of the substrate by selectively achieving surface modification in areas where growth is not desired, and then selectively depositing a thin film only in the growth area due to the selective reaction of the precursor and reactor used in the subsequent ALD deposition process.

### SUMMARY

An object of the present invention is to provide a method of forming an insulating layer pattern that can obtain a highly uniform and high-density single-molecule selective blocking layer and insulating layer using a dry technique such as atomic layer deposition.

Furthermore, another object of the present invention is to provide a method for forming an insulating layer pattern that can achieve cost and quality advantages. While the method of forming a blocking layer in the prior art, which primarily is based on dip-coating, takes at least several hours, the method according to the present invention can form selective blocking and insulating layers within minutes using the same insulating layer formation equipment without external exposure.

In addition, an object of the present invention is to provide a method for forming an insulating layer pattern that can create an insulating layer pattern with excellent selectivity on two or more types of dielectric layers, such as silicon nitride and silicon oxide, without requiring an additional mask, and a precursor for forming a blocking layer used during the process.

In addition, an object of the present invention is to provide a semiconductor device having an insulating layer pattern with high selectivity.

The above-mentioned objects and other objects will be described in detail below.

To address the above challenges, in an aspect, the present disclosure provides a method for forming an insulating layer pattern, which includes the steps of: providing a substrate comprising two or more different types of dielectric layer regions; and selectively forming a blocking layer to include a first region on the substrate where the blocking layer is formed and a second region where no blocking layer is formed or relatively less amount of blocking layer is formed. A difference in water contact angle between the first region and the second region is within the range of 7 to 50 degrees.

In addition, the present disclosure provides a precursor used to selectively form a blocking layer on a substrate with two or more different types of dielectric layer regions. In particular, the precursor is represented by the chemical formula 1 or chemical formula 2:

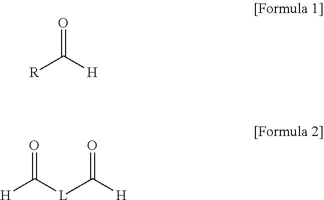

In Formula 1,
R is a substituted or unsubstituted C1-C30 alkyl group, a substituted or unsubstituted C2-C30 alkenyl group, a substituted or unsubstituted C1-C30 alkoxy group, a substituted or unsubstituted C1-C30 sulfide group, a substituted or unsubstituted C6-C50 aryl group, a substituted or unsubstituted C7-C50 aralkyl group, or a substituted or unsubstituted C2-C50 heteroaryl group. However, when the alkyl group contains 10 or more carbon atoms, one or more hydrogens of the alkyl group are substituted with halogen.
L is a substituted or unsubstituted C1-30 alkylene group, a substituted or unsubstituted C2-C30 alkenylene group, a substituted or unsubstituted C1-C30 alkyleneoxy group, or a substituted or unsubstituted C1-C30 sulfide group, a substituted or unsubstituted C3-C50 cycloalkylene group, a substituted or unsubstituted C6-C50 arylene group, a substituted or unsubstituted C2-C50 heteroarylene group, or a combination thereof.

In addition, the present disclosure provides a semiconductor device comprising: a substrate including two or more different types of dielectric layer regions; and a silicon oxide insulating layer formed on the substrate. The silicon oxide insulating layer includes a second region in which the silicon oxide insulating layer is selectively formed and a first region in which the silicon oxide insulating layer is not formed or relatively less formed. A thickness difference between the silicon oxide insulating layer formed on the first region and the second region is 0.8 nm or more.

The present invention can obtain a very uniform and high-density single molecule blocking layer by using a dry technique such as atomic layer deposition to form a blocking layer.

In addition, while the method of forming a blocking layer in the prior art, i.e., dip-coating, takes at least several hours, the present invention can form selective blocking and insulating layers within minutes using the same insulating layer formation equipment without external exposure. As a result, cost and quality advantages can be obtained.

In addition, an insulating layer pattern can be formed with excellent selectivity on two or more types of dielectric layers, such as silicon nitride and silicon oxide, without an additional mask.

The above effects and other effects will be described in detail below.

### BRIEF DESCRIPTION OF THE DRAWING

FIG. 1 is a process flow diagram of a method for forming an insulating layer pattern according to an embodiment of the present disclosure.

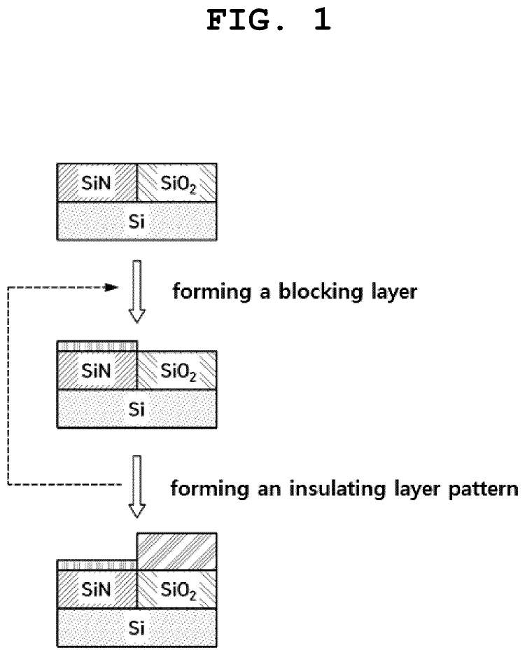

### DETAILED DESCRIPTION

Prior to a description of the present disclosure, it should be noted that the terms used in the present specification are used only to describe specific examples and are not intended to limit the scope of the present disclosure which will be defined only by the appended claims. Unless otherwise defined herein, all terms including technical and scientific terms used herein have the same meaning as commonly understood by those who are ordinarily skilled in the art to which the present disclosure pertains.

Unless otherwise stated herein, it will be further understood that the terms “comprise”, “comprises”, and “comprising”, when used in this specification, specify the presence of stated features, regions, integers, steps, operations, elements and/or components but do not preclude the presence or addition of one or more other features, regions, integers, steps, operations, elements, components and/or groups thereof.

Throughout the specification and claims of the disclosure, the term “aryl” refers to a functional group having a C5-50 aromatic hydrocarbon ring, and examples thereof include phenyl, benzyl, naphthyl, biphenyl, terphenyl, fluorene, phenanthrenyl, triphenylenyl, perylenyl, chrysenyl, fluoranthenyl, benzofluorenyl, benzotriphenylenyl, benzochrysenyl, anthracenyl, stilbenyl, or pyrenyl. The term “heteroaryl” refers to a C2-50 aromatic ring structure containing at least one heteroatom, and it includes a heterocyclic ring formed from pyrrolyl, pyrazinyl, pyridinyl, indolyl, isoindolyl, furyl, benzofuranyl, isobenzofuranyl, dibenzofuranyl, benzothiophenyl, dibenzothiophenyl, quinolyl group, isoquinolyl, Quinoxalinyl, carbazolyl, phenanthridinyl, acridinyl, phenanthrolinyl, thienyl, a pyridine ring, a pyrazine ring, a pyrimidine ring, a pyridazine ring, a triazine ring, an indole ring, a quinoline ring, an acridine ring, a pyrrolidine ring, a dioxane ring, a piperidine ring, a morpholine ring, a piperazine ring, a carbazole ring, a furan ring, a thiophene ring, an oxazole ring, an oxadiazole ring, a benzofuran ring, a thiazole ring, a thiadiazole ring, a benzothiophene ring, a triazole ring, an imidazole ring, a benzoimidazole ring, a pyran ring, or a dibenzofuran ring.

In chemical formulas: Arx (where x is an integer) means a substituted or unsubstituted C6-C50 aryl group, or a substituted or unsubstituted C2-C50 heteroaryl group, unless otherwise defined; Lx (where x is an integer) means a directly bonded and a substituted or unsubstituted C6-C50 arylene group or a substituted or unsubstituted C2-C50 heteroarylene group, unless otherwise defined; and Rx (where x is an integer), means a hydrogen, deuterium, halogen, a nitro group, a nitrile group, a substituted or unsubstituted C1-C30 alkyl group, a substituted or unsubstituted C2-C30 alkenyl group, a substituted or unsubstituted C1-C30 alkoxy group, a substituted or unsubstituted C1-C30 sulfide group, a substituted or unsubstituted C6-C50 aryl group, or a substituted or unsubstituted C2-C50 heteroaryl group, unless otherwise defined.

Throughout the present specification and claims, the term “substituted or unsubstituted” means that a portion is substituted or unsubstituted by at least one selected from the group consisting of deuterium, halogen, amino group, cyano group, nitrile group, nitro group, nitroso group, sulfamoyl group, isothiocyanate group, thiocyanate group, carboxyl group, carbonyl group, C1-C30 alkyl group, C1-C30 alkylsulfinyl group, C1-C30 alkylsulfonyl group, C1-C30 alkylsulfanyl group, C1-C12 fluoroalkyl group, C2-C30 alkenyl group, C1-C30 alkoxy group, C1-C12 N-alkylamino group, C2-C20 N, N-dialkylamino group, substituted or unsubstituted C1-C30 sulfide group, C1-C6 N-alkylsulfamoyl group, C2-C12 N, N-dialkylsulfamoyl group, C0-C30 silyl group, C3-C20 cycloalkyl group, C3-C20 heterocycloalkyl group, C6-C50 aryl group, and C2-C50 heteroaryl group, etc. However, the present disclosure is not particularly limited thereto. In addition, the same symbols throughout the present specification may have the same meaning unless otherwise specified.

All or some embodiments described herein may be selectively combined and configured so that the embodiments may be modified in various ways unless the context clearly indicates otherwise. Hereinafter, embodiments of the present disclosure and the effects thereof will be described in detail below.

A method for forming an insulating layer pattern according to an embodiment of the present invention includes providing a substrate including two or more different types of dielectric layer regions, and selectively forming a blocking layer to include a first region on the substrate where the blocking layer is formed and a second region where no or less blocking layer is formed.

A difference in water contact angle between the first region and the second region may be within the range of 7 to 50 degrees, and specifically may be within the range of 7 to 40 degrees. Within the above range, an insulating layer can be formed with high selectivity.

After selectively forming the blocking layer, the method may further include forming a silicon oxide insulating layer on the second region where the blocking layer is not formed or relatively less formed.

Here, the meaning of “selective” includes both cases where only one element is wholly selected and cases where one element is selected relatively more than the other element.

The surfaces of two or more different types of dielectric layer regions of the substrate may include an amine-terminated silicon region and a hydroxy-terminated silicon region. In a specific embodiment of the present invention, an insulating layer pattern can be formed by selectively forming a blocking layer by dividing the amine-terminated silicon region and a hydroxy-terminated silicon region and then selectively forming an insulating layer. The amine-terminated silicon region may specifically include a silicon nitride layer, and the hydroxy-terminated silicon region may specifically include a silicon oxide layer.

Meanwhile, in order to further increase selectivity, the step of pre-treating the substrate including the dielectric layer region may be further included before selectively forming the blocking layer.

When pretreatment is performed in this way, the difference in water contact angle between the first and second regions increases to a range of 22 to 40 degrees (Deg), resulting in a large difference in surface reactivity between the precursor used to form the blocking layer and the two regions. The difference in surface reactivity allows the blocking layer to be more selectively formed in the first region and the insulating layer to be selectively formed in the second region.

The step of pretreating the substrate is not limited, and specifically includes the following method. For example, a method of dipping the substrate in an HF aqueous solution or thermal annealing in an HF gas atmosphere may be used. As another example, thermal annealing or plasma treating of the substrate in a gas atmosphere of N2, H2, ammonia, hydrazine, or a mixture thereof may be performed.

The pretreatment performed by the vapor phase process described above may use deposition equipment such as ALD or CVD, and the pretreatment may be performed within a temperature range of 0 to 800° C. of the substrate.

In the step of selectively forming the blocking layer, various methods using gas-phase reaction, such as CVD (Chemical Vapor Deposition) and ALD (Atomic Layer Deposition), may be used. Specifically, the step of selectively forming a blocking layer includes the first step of supplying a precursor for forming a blocking layer and the second step of purging, and the steps may be repeated two or more times. The purging uses an inert gas, and the inert gas may be one or more of nitrogen (N2), argon, neon, or helium.

The precursor for forming a blocking layer according to an embodiment of the present invention may be represented by Formula 1 or Formula 2 below.

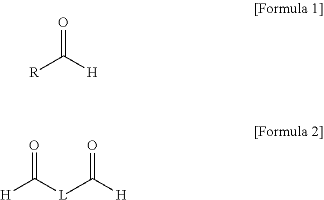

In Formula 1,
R is a substituted or unsubstituted C1-C30 alkyl group, a substituted or unsubstituted C2-C30 alkenyl group, a substituted or unsubstituted C1-C30 alkoxy group, a substituted or unsubstituted C1-C30 sulfide group, a substituted or unsubstituted C6-C50 aryl group, a substituted or unsubstituted C7-C50 aralkyl group, or a substituted or unsubstituted C2-C50 heteroaryl group. When the alkyl group contains 10 or more carbon atoms, one or more hydrogens of the alkyl group are substituted with halogen.
L is a substituted or unsubstituted C1-C30 alkylene group, a substituted or unsubstituted C2-C30 alkenylene group, a substituted or unsubstituted C1-C30 alkyleneoxy group, or a substituted or unsubstituted C1-C30 sulfide group, a substituted or unsubstituted C3-C50 cycloalkylene group, a substituted or unsubstituted C6-C50 arylene group, a substituted or unsubstituted C2-C50 heteroarylene group, or a combination thereof.

When substituted, the substituent may be at least one selected from the group consisting of deuterium, halogen, amino group, cyano group, nitrile group, nitro group, nitroso group, sulfamoyl group, isothiocyanate group, thiocyanate group, carboxyl group, C1-C30 alkyl group, C1-C30 alkylsulfinyl group, C1-C30 alkylsulfonyl group, C1-C30 alkylsulfanyl group, C1-C12 fluoroalkyl group, C2-C30 alkenyl group, C1-C30 alkoxy group, C1-C12 N-alkylamino group, C2-C20 N, N-dialkylamino group, substituted or unsubstituted C1-C30 sulfide group, C1-C6 N-alkylsulfamoyl group, C2-C12 N, N-dialkylsulfamoyl group, C0-C30 silyl group, C3-C20 cycloalkyl group, C3-C20 heterocycloalkyl group, C6-C50 aryl group, and C2-C50 heteroaryl group.

Specifically, in R, one or more hydrogens bonded to carbon may be substituted with halogen. Specifically, the halogen may be fluorine.

Specifically, R may be a C1-C20 alkyl group substituted with one or more fluorines or a C6-C50 aryl group substituted with one or more fluorines.

The step of forming a silicon oxide insulating layer on the second region where the blocking layer is not formed or relatively less formed, is performed by using sputtering, CVD (Chemical Vapor Deposition), or ALD (Atomic Layer Deposition) method, etc.

Specifically, in the step of forming the silicon oxide insulating layer, as an oxygen source, one or more selected from the group consisting of oxygen, hydrogen peroxide, ozone, nitrogen monoxide, water plasma, oxygen plasma, residual water in the chamber, and oxygen may be used. As a nitrogen source, one or more selected from the group consisting of ammonia, hydrazine, alkylhydrazine, dialkylhydrazine, nitrogen plasma, plasma of a mixed gas of nitrogen and hydrogen, ammonia plasma, plasma of a mixed gas of ammonia and hydrogen, and mixtures thereof may be used.

The formation of a silicon oxide insulating layer can be performed by repeating the four-step unit process of supplying primary raw material (Si precursor)-purging-supplying secondary raw material (reactant)-purging, as in a typical ALD step. Additionally, the dielectric layer forming process may repeat the cycle until a layer having a predetermined thickness is achieved.

Additionally, when repeating the silicon oxide insulating layer forming process cycle, a step of selectively forming the above-described blocking layer may be added in the middle of the cycle to increase selectivity.

When using the Si precursor as the primary raw material, examples of the Si precursor may be silanes, and the silanes may be specifically selected from SiH4, Diisoprophylamino Silane (DIPAS), Bis-Diethylamino Silane (BDEAS), Tris(dimethylamino)silane (TDMAS), Bis(t-butylamino)silane (BTBAS), or combinations thereof. The reactant used as the secondary raw material may be the previously exemplified oxygen source or nitrogen source.

During the silicon oxide insulating layer forming process, the purging may be performed by using an inert gas, and the inert gas used in the step of selectively forming a blocking layer may be used.

When the silicon oxide insulating layer forming process is performed, the blocking layer may be removed during the process, or all or part of the blocking layer may remain.

As an embodiment of the present invention, a semiconductor device is provided, comprising a substrate including two or more different types of dielectric layer regions, and a silicon oxide insulating layer formed on the substrate. The silicon oxide insulating layer includes a second region in which the silicon oxide insulating layer is selectively formed and a first region in which the silicon oxide insulating layer is not formed or relatively less formed, wherein the thickness difference between the silicon oxide insulating layer formed on the first region and the second region is 0.8 nm or more, specifically 2.2 nm or more.

Here, the description for the same configuration and structure is omitted to avoid obscuring the disclosure.

In a semiconductor device according to an embodiment of the present invention, a silicon oxide insulating layer is selectively formed on two or more types of dielectric layer regions, so that the thickness difference between the insulating layers is 0.8 nm or more, and a highly selective insulating layer pattern can be obtained without using a separate mask pattern. In particular, when the substrate is pre-treated, the selectivity is even better and the thickness difference of the insulating layer can be increased to 2.2 nm or more.

Hereinafter, the present invention will be described in more detail with specific examples. The following examples are merely illustrative of the present invention, and the scope of the present invention is not limited to the following examples.

### <Experimental Example 1>Method of Forming a Blocking Layer

In this experimental example, a traveling method of atomic layer deposition was introduced to form a blocking layer. The precursor for forming the blocking layer was used in a canister, and the canister temperature was maintained at a constant temperature between-20 and 100° C. to ensure stable supply.

The ALD process was performed in one cycle: precursor injection for blocking layer formation-purge, and high purity nitrogen (300 sccm) was used as purge gas. The cycle was repeated 1 to 100 times as needed. As substrates, Si3N4 and SiO2 wafers were used with HF aqueous solution treatment or without treatment, respectively. The temperature of the substrate was tested by adjusting it between 0 and 500° C. The results of the blocking layer formation were confirmed using a water contact angle analyzer, and the results are shown in Table 1 below.

TABLE 1

| | | No pretreatment | | | Pretreated with HF aqueous solution | | |
|---|---|---|---|---|---|---|---|
| | Pretreated or not | SiO2 | SiN | | SiO2 | SiN | |
| | Precursor for | area | area | contact | area | area | contact |
| | forming a blocking | contact | contact | angle | contact | contact | angle |
| Classification | layer | angle | angle | difference | angle | angle | difference |
| Comparative | Unapplied | 25.0 | 28.1 | 3.1 | 13.4 | 27.8 | 14.4 |
| Example 1 | | | | | | | |
| Comparative | undecanal | 39.0 | 45.6 | 6.6 | 31.4 | 52.8 | 21.4 |
| Example 2 | | | | | | | |
| Example 1 | 11- | 39.7 | 48.5 | 8.8 | 29.6 | 54.9 | 25.3 |
| | fluoroundecanal | | | | | | |
| Example 2 | 4- | 39.0 | 49.2 | 10.2 | 27.1 | 56.0 | 28.9 |
| | (trifluoromethyl) | | | | | | |
| | benzaldehyde | | | | | | |
| Example 3 | 2,3,4,5,6- | 40.7 | 49.3 | 8.6 | 32.6 | 60.6 | 28.0 |
| | pentafluorobenzaldehyde | | | | | | |
| Example 4 | 7H- | 49.1 | 60.1 | 11.0 | 44.7 | 77.3 | 32.6 |
| | dodecafluoroheptanal | | | | | | |
| Example 5 | Isophthalaldehyde | 43.4 | 52.7 | 9.3 | 28.5 | 56.7 | 28.2 |
| Example 6 | 1,8- | 38.5 | 50.2 | 11.7 | 31.4 | 66.0 | 34.6 |
| | Octanedialdehyde | | | | | | |
| Example 7 | 2,2,3,3,4,4,5,5- | 49.8 | 63.6 | 13.8 | 42.7 | 79.7 | 37.0 |
| | Octafluorohexanedialdehyde | | | | | | |

As shown in Table 1, when a blocking layer was formed as in Examples 1 to 7, the contact angle difference was more than 8 degrees, specifically in the range of 8.6 to 13.8 degrees. It can be seen that the contact angle difference was significantly larger compared to the contact angle difference of 3.1 degrees (Deg) in Comparative Example 1 in which no blocking layer was formed. In addition, in the case of Comparative Example 1, which had one aldehyde group, 10 or more carbon atoms in the alkyl group, and no fluorine substituent, the contact angle difference was relatively small at 6.6 degrees.

In addition, it can be seen that by pretreating the substrate, the contact angle difference was able to be significantly increased to more than 22 degrees, specifically in the range of 22 to 40 degrees, compared to the case without pretreatment.

### <Experimental Example 2>Formation of Silicon Oxide Insulating Layer

In this experimental example, traveling-type atomic layer deposition was introduced, and SiO2 layer formation was evaluated using DIPAS (Di-isopropylamino Silane) as a Si precursor and ozone (03) as a reactant. The Si precursor was used in a canister, and the process was carried out without any additional heating.

The ALD process was carried out in one cycle: Si precursor injection-purge-reactants injection-purge, and high purity nitrogen was used as purge gas. The cycle was repeated 1 to 200 times until a desired thickness was reached, and a blocking layer deposition process could be added between these processes. As a substrate, the Si3N4 and SiO2 wafers with the blocking layers of Experimental Example 1 were used. The temperature of the substrate was tested by adjusting it between 25 and 300° C. The thickness of the thin layer was measured using an ellipsometer and the results are shown in Table 2.

TABLE 2

| | | | | | Pretreated with HF | | |
|---|---|---|---|---|---|---|---|
| | | No pretreatment | | | aqueous solution | | |
| | | SiO2 | SiN | | SiO2 | SiN | |
| | Pretreated | area | area | | area | area | |
| | or not | insulation | insulation | | insulation | insulation | |
| | forming a | layer | layer | | layer | layer | |
| | blocking | thickness | thickness | Thickness | thickness | thickness | Thickness |
| Classification | layer | (nm) | (nm) | difference | (nm) | (nm) | difference |
| Comparative | Unapplied | 8.0 | 7.7 | 0.3 | 8.3 | 7. | 1.2 |
| Example 3 | | | | | | | |
| Comparative | undecanal | 7.8 | 7.1 | 0.7 | 7.7 | 5.6 | 2.1 |
| Example 4 | | | | | | | |
| Example 8 | 11- | 7.6 | 6.8 | 0.8 | 8.1 | 5.3 | 2.8 |
| | fluoroundecanal | | | | | | |
| Example 9 | 4- | 7.7 | 6.7 | 1.0 | 8.0 | 4.4 | 3.6 |
| | (trifluoromethyl)benzaldehyde | | | | | | |
| Example 10 | 2,3,4,5,6- | 7.1 | 6.3 | 0.8 | 8.1 | 5.1 | 3.0 |
| | pentafluorobenzaldehyde | | | | | | |
| Example 11 | 7H- | 7.5 | 6.4 | 1.1 | 8.1 | 3.7 | 4.4 |
| | dodecafluoroheptanal | | | | | | |
| Example 12 | Isophthalaldehyde | 7.4 | 6.5 | 0.9 | 8.5 | 5.3 | 3.2 |
| Example 13 | 1,8- | 7.7 | 6.4 | 1.3 | 8.2 | 3.7 | 4.5 |
| | Octanedialdehyde | | | | | | |
| Example 14 | 2,2,3,3,4,4,5,5- | 7.6 | 6.1 | 1.5 | 8.4 | 3.4 | 5.0 |
| | Octafluorohexanedialdehyde | | | | | | |

As shown in Table 2, when a blocking layer was formed as in Examples 8 to 14, the difference in the thickness of the insulating layer was 0.8 nm or more, specifically in the range of 0.8 nm to 1.5 nm. It can be seen that the difference in insulating layer thickness was significantly larger compared to the 0.3 nm difference in insulating layer thickness in Comparative Example 3 in which no blocking layer was formed. In addition, in the case of Comparative Example 4, which had one aldehyde group, 10 or more carbon atoms in the alkyl group, and no fluorine substituent, the difference in the thickness of the insulating layer was relatively small at 0.7 nm.

In addition, it can be seen that by pre-treating the substrate, the insulating layer thickness difference was able to be significantly increased to 2.2 nm or more, specifically in the range of 2.8 nm to 5.0 nm, compared to the case without pre-treatment.

What is claimed is:

1. A method for forming an insulating layer pattern, comprising:
providing a substrate comprising two or more different types of dielectric layer regions; and
selectively forming a blocking layer on the substrate to include a first region where the blocking layer is formed and a second region where no blocking layer is formed or the blocking layer is formed less than in the first region,
wherein a difference in water contact angle between the first region and the second region is within a range of 7 to 50 degrees.

2. The method of claim 1, further comprising:
forming a silicon oxide insulating layer on the second region.

3. The method of claim 1, further comprising:
pre-treating the substrate before selectively forming the blocking layer.

4. The method of claim 3, wherein the difference in water contact angle between the first region and the second region is within a range of 22 to 40 degrees after the step of pre-treating the substrate.

5. The method of claim 3, wherein the step of pre-treating the substrate comprises dipping in an HF solution or thermal annealing in an HF gas atmosphere.

6. The method of claim 3, wherein the step of pre-treating the substrate comprises thermal annealing or plasma treating of the substrate in a gas atmosphere of N2, H2, ammonia, hydrazine, or a mixture thereof.

7. The method of claim 1, wherein the surfaces of the dielectric layer of the substrate include an amine-terminated silicon region and a hydroxy-terminated silicon region.

8. The method of claim 1, wherein the dielectric layer of the substrate includes a silicon nitride layer region and silicon oxide layer region.

9. The method of claim 2, wherein the step of forming a silicon oxide insulating layer is performed by using sputtering, Chemical Vapor Deposition (CVD), or Atomic Layer Deposition (ALD).

10. The method of claim 2, wherein the precursor used to form the silicon oxide insulating layer is selected from the group consisting of SiH4, Diisoprophylamino Silane (DIPAS), Bis-Diethylamino Silane (BDEAS), Tris(dimethylamino)silane (TDMAS), Bis(t-butylamino)silane (BTBAS), and a combination thereof.

11. A precursor used to selectively form a blocking layer on a substrate with two or more different types of dielectric layer regions, wherein the precursor is represented by the chemical formula 1 or chemical formula 2: 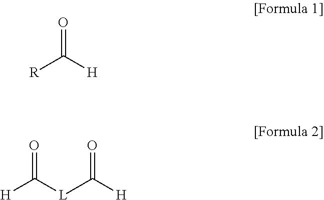
wherein, in Formula 1,
R is a substituted or unsubstituted C1-C30 alkyl group, a substituted or unsubstituted C2-C30 alkenyl group, a substituted or unsubstituted C1-C30 alkoxy group, a substituted or unsubstituted C1-C30 sulfide group, a substituted or unsubstituted C6-C50 aryl group, a substituted or unsubstituted C7-C50 aralkyl group, or a substituted or unsubstituted C2-C50 heteroaryl group, wherein, when the alkyl group contains 10 or more carbon atoms, one or more hydrogens of the alkyl group are substituted with halogen, and
L is a substituted or unsubstituted C1-C30 alkylene group, a substituted or unsubstituted C2-C30 alkenylene group, a substituted or unsubstituted C1-C30 alkyleneoxy group, or a substituted or unsubstituted C1-C30 sulfide group, a substituted or unsubstituted C3-C50 cycloalkylene group, a substituted or unsubstituted C6-C50 arylene group, a substituted or unsubstituted C2-C50 heteroarylene group, or a combination thereof.

12. The precursor of claim 11, wherein the substituent is at least one selected from the group consisting of deuterium, halogen, amino group, cyano group, nitrile group, nitro group, nitroso group, sulfamoyl group, isothiocyanate group, thiocyanate group, carboxyl group, C1-C30 alkyl group, C1-C30 alkylsulfinyl group, C1-C30 alkylsulfonyl group, C1-C30 alkylsulfanyl group, C1-C12 fluoroalkyl group, C2-C30 alkenyl group, C1-C30 alkoxy group, C1-C12 N-alkylamino group, C2-C20 N, N-dialkylamino group, substituted or unsubstituted C1-C30 sulfide group, C1-C6 N-alkylsulfamoyl group, C2-C12 N, N-dialkylsulfamoyl group, C3-C30 silyl group, C3-C20 cycloalkyl group, C3-C20 heterocycloalkyl group, C6-C50 aryl group, and C2-C50 heteroaryl group.

13. A semiconductor device comprising:
a substrate including two or more different types of dielectric layer regions; and
a silicon oxide insulating layer formed on the substrate,
wherein the silicon oxide insulating layer includes a first region and a second region in which the silicon oxide insulating layer is selectively formed such that, in the second region, the silicon oxide insulating layer is formed, and in the first region, no silicon oxide insulating layer is formed or the silicon oxide insulating layer is formed less than in the second region, and
wherein a thickness difference between the silicon oxide insulating layer formed on the first region and the second region is 0.8 nm or more.

14. The semiconductor device of claim 13, wherein the thickness difference between the silicon oxide insulating layer formed on the first region and the second region is 2.2 nm or more.
